(19) United States
(12) Patent Application Publication
(10) Pub. No.: US 2010/0200059 A1
(43) Pub. Date: Aug. 12, 2010

(54) DUAL-SIDE LIGHT-ABSORBING THIN FILM SOLAR CELL

(76) Inventors: Wei-Lun LU, Houli Township (TW); Chl-Hung Yeh, Houli Township (TW); Chlen-Pang Yang, Houli Township (TW)

Correspondence Address: SINORICA, LLC, 2275 Research Blvd., Suite 500, ROCKVILLE, MD, 20850, US

(21) Appl. No.: 12/704,182

(22) Filed: Feb. 11, 2010

(30) Foreign Application Priority Data
Feb. 12, 2009 (TW) 098104491

(51) Int. Cl. H01L 31/00

(52) U.S. Cl. 136/256

(57) ABSTRACT

The present invention discloses a dual-side light-absorbing thin film solar cell that comprises a substrate, a p-type transparent conductive layer, a semiconductive film and a transparent conductive layer. The p-type transparent conductive layer is formed on the substrate and its material is a p-type transparent conductive material, for example, CuMO₂, Cu_{2X}Sr_{X}O₂, or others. M is a IIIA element that is aluminum (Al), boron (B), gallium (Ga), indium (In), or thallium (Tl), and X is greater than zero. The semiconductive film is formed on the p-type transparent conductive layer. The semiconductive film comprises a p-type semiconductive layer and a n-type semiconductive layer. The n-type semiconductive layer is formed on the p-type semiconductive layer. The transparent conductive layer is formed on the semiconductive film. Such structure allows lights enter through both sides of the thin film solar cell so that the efficiency of the elements and the photoelectric conversion rate is improved.

### BACKGROUND OF THE INVENTION

1. Field of the Invention

The present invention relates to a solar cell, more particular to a dual-side light-absorbing thin film solar cell has an elevated light-absorbing rate and photoelectric conversion efficiency resulted from the disposition of a p-type transparent conductive layer.

2. Description of the Prior Art

Solar cells provide a clean, reliable, and replaceable energy and to relief the increasing need of the global energy requirement. The three main categories of the present solar cells are crystalline silicon, thin film, and organic materials. The development of the thin film solar cell results in the decrease of manufacturing cost as well as photoelectric conversion efficiency. The materials used in the thin film solar cell mainly comprises cadmium tellurium (CdTe), amorphous silicon, copper indium gallium diselenide (Cu(In, Ga)Se₂, CIGS). The copper indium gallium is a semiconductive material with a direct band gap. The band gap covers almost the whole spectrum of sunlight. The copper indium gallium diselenide has a high light-absorbing coefficient, great thermo-stability, and illuminating stability so therefore it is suitable for being made of the light-absorbing layer of the thin film solar cell. In addition, the material of the thin film solar cell is cheaper and the manufacturing cost is lower than the crystalline silicon solar cell and the element efficiency is the highest among the thin film solar cell (almost up to 19.9%). Therefore, the CIGS-based thin film solar cell is one of the solar cells having a great developing potential.

The CIGS-based thin film solar cell has a multilayer structure. In general, the bottom layer uses a soda-lime glass to serve as a substrate. A layer of molybdenum is deposited on the substrate to serve as the back electrode. A CIGS-based p-type semiconductor is then deposited on the back electrode to serve as the light-absorbing layer. A n-type buffer layer of cadmium sulfide (CdS) or zinc sulfide (ZnS), a pure i-ZnO layer, and a transparent conductive layer of zinc oxide are serially deposited on the CIGS layer in such sequence. The top layer is a metal layer of Ni/Al to serve as a top electrode layer.

The electricity-generation part of the CIGS-based thin film solar cell is the p-type CIGS light-absorbing layer, the n-type buffer layer, and the transparent conductive oxide layer. When these elements are not exposed under light, because the distribution of the concentration of electrons is not even, electrons diffuses from the n-type buffer layer and the transparent conductive oxide layer to the p-type CIGS light-absorbing layer. And the electron holes having the opposing polarity move in a direction opposing to that of the electrons. As a result, parts of the n-type buffer layer, and the transparent conductive oxide layer are electrically positive and parts of the p-type CIGS-based light-absorbing layer are electrically negative, and a space charge region (SRC) and a built-in electric field are therefore formed near the junction. When the photon energy (hv) is greater than band gap the semiconductor, electrons are excited from the valance band (Ev) to the conduction band (Ec) to become free conductive carriers (electrons). A photo-generated electron diffuses to the peripheral of the space charge region and are then dragged by the built-in electric field to drift to the region of the n-type buffer layer and the transparent conductive oxide layer. On the contrary, the electron holes drift toward the p-type CIGS-base light-absorbing layer. As a result, a photocurrent is generated.

The key points in the development of the solar cell and the green power comprise the elevation of the element efficiency and the decrease of the manufacturing cost. To the aspect of the elevation of the element efficiency, although the element efficiency of the CIGS-based thin film solar cell is highest among the thin film solar cell, it remains to be improved when compared with other categories of solar cells. In addition, an incident light can enter into the solar cell only through the top electrode layer, which can not improve the photoelectric conversion efficiency of the light-absorbing layer. Therefore, it is important to develop a thin film solar cell having an improved element efficiency and photoelectric conversion rate.

### SUMMARY OF THE INVENTION

To solve the aforementioned shortcomings of the conventional CIGS solar cell having a poor efficiency of the element and the photoelectric conversion rate, the present invention provides a dual-side light-absorbing thin film solar cell that utilizes the disposing of the layer having is controllable and adjustable band gap (Eg), conductivity, light transmittance, and work function to elevate the output voltage. In addition, such structure allows lights enter through both sides of the thin film solar cell so that the incident light amount is increased. Therefore, the object to improve the efficiency of the elements and the photoelectric conversion rate is also achieved.

In order to achieve the aforementioned object, the present invention provides a dual-side light-absorbing thin film solar cell that comprises a substrate, a p-type transparent conductive layer, a semiconductive film and a transparent conductive layer. The material from which the substrate is made can be glass, quartz, transparent plastics or flexible transparent plastic material. The p-type transparent conductive layer is formed on the substrate and its material is a p-type transparent conductive material, for example, CuMO₂, Cu_{2X}Sr_{X}O₂, or others. M is a IIIA element that is aluminum (Al), boron (B), gallium (Ga), indium (In), or thallium (Tl), and X is greater than zero. When the material of the p-type transparent conductive layer is copper aluminum dioxide (CuAlO₂), the layer has a thickness of at least 50 nm and the ratio of copper and/or aluminum ranges from 0.8 to 1.2. The p-type transparent conductive layer can be formed by DC reactive sputtering using a copper aluminum alloy target, or formed by radio frequency (RF) sputtering using a copper aluminum dioxide target. The semiconductive film is formed on the p-type transparent conductive layer. The semiconductive film comprises a p-type semiconductive layer comprising copper indium gallium diselenide (Cu(In, Ga)Se₂, CIGS) and a n-type semiconductive layer comprising cadmium sulfide (CdS) or zinc sulfide (ZnS). The n-type semiconductive layer is formed on the p-type semiconductive layer. The transparent conductive layer is formed on the semiconductive film and is a transparent conductive oxide layer. The material of the transparent conductive layer can be tin-doped indium oxide (ITO), indium zinc oxide (IZO), aluminum-doped zinc oxide (AZO), boron-doped zinc oxide (BZO), gallium-doped zinc oxide (GZO), or undoped zinc oxide (ZnO). In addition, a pure i-ZnO layer can be deposited on the semiconductive film 130 to prevent short. A metal electrode layer can be formed on the transparent conductive layer. The material of the metal electrode layer can be aluminum, nickel, gold, silver, chromium, titanium or palladium.

The band gap (Eg), conductivity, light transmittance, and the work function of the p-type transparent conductive layer consisting of copper aluminum dioxide (CuAlO₂) are controllable and adjustable by altering the processing temperature or the oxygen partial pressure. In addition, the difference of the work function between the p-type transparent conductive layer and the p-type semiconductive layer can also be changed by altering the work function of the copper aluminum dioxide (CuAlO₂) resulted from varying the ratio of copper and/or aluminum. Therefore, when an incident light enter to the p-type transparent layer and the semiconductive film through the substrate or the transparent conductive layer, a band tail transition is occurred in the p-type semiconductive layer, which results in that electron holes of the p-type semiconductive layer will pass through the band tail transition area by tunneling effect and soon enter into the p-type transparent conductive layer. As a result, the electron holes of the p-type transparent conductive layer are accumulated and the output voltage is therefore elevated.

By controlling and adjusting the light transmittance and the work function of the p-type transparent conductive layer, the properties of the p-type transparent conductive layer will then meet the requirement of the dual-side light-absorbing thin film solar cell of the present invention. For example, elevating the light transmittance will allow a light enter into the semiconductive film. In addition, the difference of the work function between the p-type transparent conductive layer and the p-type semiconductive layer can also be changed by altering the ratio of copper and/or aluminum of the material, which results in the elevation of the output voltage. In addition, such design of the structure of the solar cell the present invention allows lights enter through both sides of the thin film solar cell so that the incident light amount is increased and the light-absorbing rate of the semiconductive layer. Therefore, the object to improve the efficiency of the elements and the photoelectric conversion rate is achieved.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a sectional view of the dual-side light-absorbing thin film solar cell according to the preferred embodiment of the present invention. The grey arrow represents an incident light;

FIG. 2 portrays the band distribution of each junction of the p-type transparent conductive layer, semiconductive film, and the transparent conductive layer in the dual-side light-absorbing thin film solar cell when it is illuminated. The grey mesh area in this figure represents the accumulation of the electron holes.

### DESCRIPTION OF THE PREFERRED EMBODIMENT

A detailed description of the present invention will be given below with reference to preferred embodiments thereof, so that a person skilled in the art can readily understand features and functions of the present invention after reviewing the contents disclosed herein.

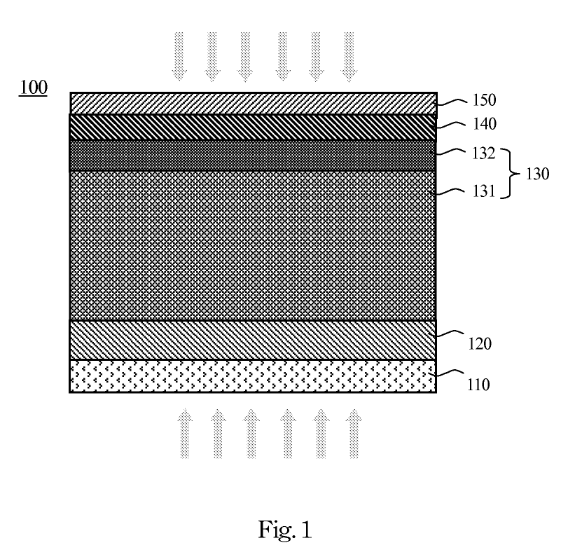

Please refer to FIG. 1 that is a sectional view of the preferred embodiment of the present invention. The preferred embodiment of the present invention is a dual-side light-absorbing thin film solar cell. The dual-side light-absorbing thin film solar cell 100 comprises a substrate 110, a p-type transparent conductive layer 120, a semiconductive film 130 and a transparent conductive layer 150. The semiconductive film 130 comprises a p-type semiconductive layer 131 and an n-type semiconductive layer 132. An incident light can enter the dual-side light-absorbing thin film solar cell 100 either from the substrate 110 or the electrode layer. Electron holes are accumulated in the p-type transparent conductive layer 120 resulted from the difference of the work function between the p-type transparent conductive layer 120 and the p-type semiconductive layer 131 and the phenomenon of band tail transition, so that the output voltage of the dual-side light-absorbing thin film solar cell 100 is increased.

The substrate 110 has one surface for the entrance of the incident light. The material from which the substrate 110 is made can be glass, quartz, transparent plastics or flexible transparent plastic material. However, the material from which the substrate 110 is made is not restricted to the above-mentioned materials. Specifically, the substrate 110 can be made of any kind of transparent materials that allow an incident light enter the dual-side light-absorbing thin film solar cell 100. If the substrate 110 is made of glass, the soda-lime glass will be preferably used because of its lower cost. In addition, the thermal expansion coefficient of the soda-lime glass is quite close to that of the p-type semiconductive layer 131. During the formation of the thin film, because the processing temperature of the substrate 110 is approximately close to the softening temperature of the soda-lime glass, thereby the sodium ions pass through the p-type transparent conductive layer 120 and diffuse to the p-type semiconductive layer 131. As a result, crystallites in the p-type semiconductive layer 131 are enlarged, the conductivity of the p-type semiconductive layer 131 is enhanced and the serial resistance of the dual-side light-absorbing thin film solar cell 100 is decreased.

The p-type transparent conductive layer 120 is formed on the other surface of the substrate 110, and has a thickness of at least 50 nm. The p-type transparent conductive layer 120 comprises a p-type transparent conductive material. On one hand, the p-type transparent conductive material can have the chemical formula: CuMO₂, and M is a IIIA element that is aluminum (Al), boron (B), gallium (Ga), indium (In), or thallium (Tl). On the other hand, the p-type transparent conductive material can have the chemical formula: Cu_{2X}Sr_{X}O₂, and X is greater than zero (for example, Cu₂SrO₂). The p-type transparent conductive material of this preferred embodiment of the present invention is copper aluminum dioxide (CuAlO₂). Copper aluminum dioxide (CuAlO₂) has a light transmittance greater than 80%. In addition, the energy gap (Eg), the conductivity, the transmittance and the work function of the copper aluminum dioxide (CuAlO₂) are controllable and adjustable. The above-mentioned work function is the energy needed to move an electron from the Fermi level into vacuum. The value of the work function represents the level of electricity matching (i.e., the level of the ohmic contact) between the copper aluminum dioxide (CuAlO₂) and the p-type semiconductive layer 131.

The aforementioned energy gap, conductivity and light transmittance can be controlled and adjusted via altering the processing temperature. For example, increasing the temperature of the substrate during the process will result in the decrease of the energy gap. And the sheet resistance is therefore decreased (i.e., the conductivity is increased and the light transmittance is increased). On the other hand, the sheet resistance of the copper aluminum dioxide (CuAlO₂) is increased (i.e., the conductivity is decreased and the light transmittance is decreased) along with the increase of the oxygen partial pressure in the process. The work function of the p-type transparent conductive material can be changed via altering the ratio of Cu, Al, or both. Generally, the most common composition of the copper aluminum dioxide is Cu_{1.0}Al_{1.0}O₂. However, according to the requirement of a specific material characteristic, either the ratio of copper or aluminum can be controlled and adjusted independently and ranges from 0.8 to 1.2. When ratio of copper is adjusted to be larger than that of the aluminum (for example, the compound expressed as Cu_{1.2}Al_{1.0}O₂), the work function is increased. On the other hand, when ratio of copper is adjusted to be smaller than that of the aluminum (for example, the compound expressed as Cu_{0.8}Al_{1.0}O₂), the work function is decreased. In addition, the energy gap of the copper aluminum dioxide (CuAlO₂) is controllable and adjustable and the copper aluminum dioxide (CuAlO₂) has a high concentration of electron holes. Therefore, the copper aluminum dioxide (CuAlO₂) has a good ohmic contact. In addition, except the aforementioned material, other materials comprising, but not being limited to, BaCu₂S₂, P-doped ZnO, As-doped ZnO and Al—N co-doped ZnO, have a good p-type transparent conductive characteristic can be applied in the present invention.

The p-type transparent conductive layer 120 consisted of the copper aluminum dioxide (CuAlO₂) can be formed by direct current (DC) reactive sputtering or radio frequency (RF) sputtering. The sputtering is the process of bombarding the target with a high-density material with energetic particles. Atoms are ejected from the target material due to the transfer of the momentum and the kinetic energy of the energetic particles and therefore the ejected atoms have sufficient energy to travel to the deposited substrate. DC sputtering used in the present invention is a process to sputtering the two metal target (copper and aluminum) onto the substrate with a DC power supply. The charging gas used in the sputtering process is mixed with a proper active gas (ex: oxygen). The active gas, under a proper partial pressure, will react with the ejected atoms to form a thin film consisted of oxide. Therefore, in a DC reactive sputtering a proper gas pressure or gas flow rate of the reaction gas is required so as to make the film have a better electrical or other characteristics. RF sputtering is to conduct the two electrodes with a radio frequency power supply. Under the effect of the modulated magnetic electrical fields, the RF sputtering apparatus can lower the pressure of the charging gas. The free electrons in the gas will collide with the molecules of gas and absorb the energy of the electrical field. Those electrons will gradually accelerated and then ionized gas molecules and more electrons are released. Those released electrons are also accelerated and in turn ionize other gas molecules. The charging process causes sputtering via the generated ions. Therefore, the RF sputtering used in the present invention can sputtering a copper aluminum dioxide (CuAlO₂) ceramic target. In addition, the process is easier and faster when a ceramic target with known ratios of copper and aluminum is sputtered.

The semiconductive film 130 has a p-n diode structure. The n-type semiconductive layer 132 is formed on the p-type semiconductive layer 131. The material of the p-type semiconductive layer 131 is preferable copper indium gallium diselenide (Cu(In, Ga)Se₂, CIGS); the material of the n-type semiconductive layer 132 is preferable cadmium sulfide (CdS) or zinc sulfide (ZnS). The n-type semiconductive layer 132 is also functioned as a buffer layer to decrease the band discontinuity between the transparent conductive layer 150 and to help electron transfer efficiently. This n-type semiconductive layer 132 can further prevent the contact of the metal and the semiconductor, which will form a parallel resistance, and protect the surface of the p-type semiconductive layer 131. The process of the photovoltaic effect occurred in the semiconductive film 130 starts from a photon entering the diode to generate an electron-electron hole pair. The electron and the electron hole are separated by the internal electrical field generated from the p-n junction of the n-type semiconductive layer 132 and the p-type semiconductive layer 131. The electron and electron hole are transferred in an opposing direction to the negative electrode and the positive electrode, respectively. The electron and electron hole are output to generate an output voltage.

On the other hand, in order to prevent decreases of the efficiency of internal elements caused by shunting during the power-releasing of the dual-side light-absorbing thin film solar cell 100, a pure i-ZnO layer 140 is deposited on the semiconductive film 130 to prevent short and protect the p-n junction.

The transparent conductive layer 150 is formed above the semiconductive film 130 and on the pure i-ZnO layer 140 in this practical embodiment. The transparent conductive layer 150 is a thin film consist of a transparent conductive oxide and has a high transmittance and low resistance, thereby functioned as an upper electrode and allowing an incident light to pass through to enter the semiconductive film 130. The material of the transparent conductive layer 150 can be tin-doped indium oxide (ITO), indium zinc oxide (IZO), aluminum-doped zinc oxide (AZO), boron-doped zinc oxide (BZO), gallium-doped zinc oxide (GZO), or undoped zinc oxide (ZnO). In addition, a metal wire can be sputtered on the transparent conductive layer 150 to serve as a top electrode. The material of the metal wire can be aluminum, nickel, gold, silver, chromium, titanium or palladium.

In the scenario that the energy gap (Eg) of both p-type transparent conductive layer 120 and the p-type semiconductive layer 131, and the difference of the valance band (Ev) and the conduction band (Ec) between both aforementioned layers are fixed values, when the photon energy (hv) entering in the dual-side light-absorbing thin film solar cell 100 through the substrate 100 and the transparent conductive layer 150 is greater than the band gap (Eg), an electron in the valance band (Ev) will be excited to the conduction band (Ec) and becomes a free conductive carrier (electron) and transfers (including drifting and diffusing) to a opposing electrode with a lower energy. Thereby, a photocurrent is generated.

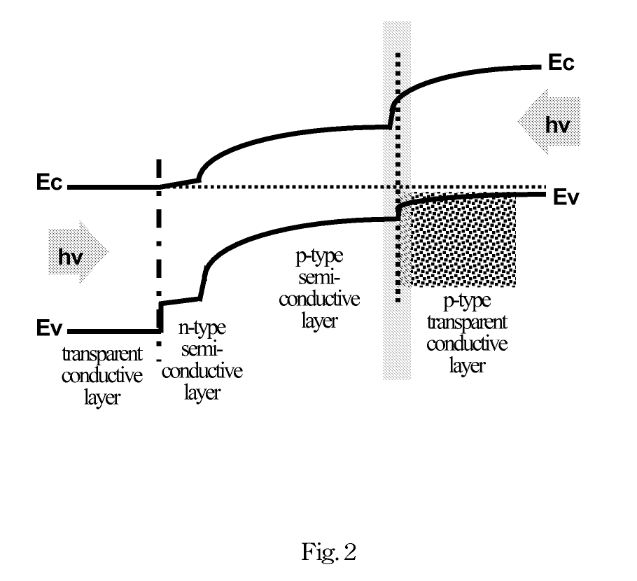

Please refer to FIG. 1 and FIG. 2. FIG. 2 portrays the band distribution of each junction of the p-type transparent conductive layer, semiconductive film, and the transparent conductive layer in the dual-side light-absorbing thin film solar cell when it is illuminated. As described previously, in the dual-side light-absorbing thin film solar cell of the present invention, the work function of the p-type transparent conductive layer 120 consisting of the copper aluminum dioxide (CuAlO₂) can be altered by adjusting the ratio of copper and/or aluminum. Alteration of the work function of the p-type transparent conductive layer 120 further results in the change of the difference of the conduction band (Ec) between the p-type transparent layer 120 and the p-type semiconductive layer 131. Furthermore, the band gap (Eg) of the p-type semiconductive layer 131 is fixed value and the band gap (Eg) of the p-type transparent conductive layer 120 can be altered by varying the temperature of the substrate or by varying the ratio of copper and/or aluminum of the copper aluminum dioxide (CuAlO₂). Therefore, the change of the difference of the conduction band (Ec) will result in the change of the difference of the valance band (Ev). That is, the greater the difference of the work function between the two layers is, the smaller the difference of the valance band (Ev) between the two layers. On the contrary, the smaller the difference of the work function between the two layers is, the greater the difference of the valance band (Ev) between the two layers.

In order to improve the efficiency of the elements and the photoelectric conversion rate of the dual-side light-absorbing thin film solar cell 100, the difference of the work function between the p-type transparent conductive layer 120 and the p-type semiconductive layer 131 should allow the electric properties of these two layers match. In this embodiment of the present invention, the difference of the valance band (Ev) is increased resulted from decrease of the difference of the work function between the p-type transparent conductive layer 120 and the p-type semiconductive layer 131. And when the difference of the valance band (Ev) between these two layers is increased, a band tail transition is occurred to form a good valance band matching between each other. When the difference of the valance band between these two layers is greater, the band tail transition is more intense. In the scenario of the same concentration of electron hole, if the band tail transition is more intense, a barrier of potential energy will be formed easier, which easily results in electron holes pass through the band tail transition area by tunneling effect. Accordingly, the electron holes separated in the p-type semiconductive layer 131 after illuminated will soon come to the p-type transparent conductive layer 120 via tunneling effect, which will results in the accumulation of the electron holes (as shown in the grey mesh area in FIG. 2). And increase of the concentration of the accumulated electron holes represents the elevation of the output voltage.

To sum up, the band gap (Eg), conductivity, light transmittance, and the work function of the p-type transparent conductive layer 120 is controllable and adjustable. And elevating the light transmittance will allow a light enter the semiconductive film 130 through the substrate 110. In addition, the difference of the work function between the p-type transparent conductive layer 120 and the p-type semiconductive layer 131 can also be changed by altering the ratio of copper and/or aluminum of the material, which results in the elevation of the output voltage. On the other hand, compared with the conventional CIGS solar cell that allows a light entering from only one side, the dual-side light-absorbing thin film solar cell of the present invention allows lights enter through both the substrate 110 and the transparent conductive layer 150 so that the incident light amount is increased. Therefore, the light-absorbing rate of the semiconductive layer 130 is also increased and the object to improve the efficiency of the elements and the photoelectric conversion rate of the dual-side light-absorbing thin film solar cell 100 is also achieved.

The present invention can also be implemented by or applied in other embodiments, where changes and modifications can be made to the disclosed details from a viewpoint different from that adopted in this specification without departing from the spirit of the present invention.

What is claimed is:

1. A dual-side light-absorbing thin film solar cell, comprising
a substrate;
a p-type transparent conductive layer formed on the substrate, and the p-type transparent conductive layer comprising a p-type transparent conductive material;
a semiconductive film formed on the p-type transparent conductive layer; and
a transparent conductive layer formed on the semiconductive film.

2. The dual-side light-absorbing thin film solar cell according to claim 1, wherein the p-type transparent conductive material has the chemical formula: CuMO₂, and M is a IIIA element and selected from the group consisting of aluminum (Al), boron (B), gallium (Ga), indium (In), and thallium (Tl).

3. The dual-side light-absorbing thin film solar cell according to claim 2, wherein the p-type transparent conductive material is copper aluminum dioxide (CuAlO₂).

4. The dual-side light-absorbing thin film solar cell according to claim 3, wherein the copper aluminum dioxide (CuAlO₂) has a Cu or Al ratio ranging from 0.8 to 1.2.

5. The dual-side light-absorbing thin film solar cell according to claim 3, wherein the p-type transparent conductive layer has a thickness of at least 50 nm.

6. The dual-side light-absorbing thin film solar cell according to claim 3, wherein the p-type transparent conductive layer is formed by DC reactive sputtering using a copper aluminum alloy target.

7. The dual-side light-absorbing thin film solar cell according to claim 3, wherein the p-type transparent conductive layer is formed by RF sputtering using a copper aluminum dioxide target.

8. The dual-side light-absorbing thin film solar cell according to claim 1, wherein the p-type transparent conductive material has the chemical formula: Cu_{2X}Sr_{X}O₂, and X is greater than zero.

9. The dual-side light-absorbing thin film solar cell according to claim 1, wherein the semiconductive film comprises a p-type semiconductive layer and an n-type semiconductive layer, and the n-type semiconductive layer is formed on the p-type semiconductive layer.

10. The dual-side light-absorbing thin film solar cell according to claim 9, wherein the p-type semiconductive layer is a copper indium gallium diselenide (Cu(In, Ga)Se₂, CIGS) layer.

11. The dual-side light-absorbing thin film solar cell according to claim 9, wherein the n-type semiconductive layer is a cadmium selenide (CdS) or zinc selenide (ZnS) layer.

12. The dual-side light-absorbing thin film solar cell according to claim 1, wherein the transparent conductive layer is a transparent conductive oxide (TCO) layer.

13. The dual-side light-absorbing thin film solar cell according to claim 12, wherein the transparent conductive oxide is selected from the group consisting of tin-doped indium oxide (ITO), indium zinc oxide (IZO), aluminum-doped zinc oxide (AZO), boron-doped zinc oxide (BZO), gallium-doped zinc oxide (GZO), and undoped zinc oxide (ZnO).

14. The dual-side light-absorbing thin film solar cell according to claim 1, wherein the substrate is selected from a soda-lime glass, quartz, a transparent plastic, and a transparent flexible material.
